(19) United States
(12) Patent Application Publication
(10) Pub. No.: US 2024/0321333 A1
(43) Pub. Date: Sep. 26, 2024

(54) MAGNETIC TUNNELING JUNCTION DEVICE CAPABLE OF MAGNETIC SWITCHING WITHOUT EXTERNAL MAGNETIC FIELD AND MEMORY DEVICE INCLUDING THE SAME

(71) Applicant: Samsung Electronics Co., Ltd., Suwon-si (KR)

(72) Inventors: Jeongchun RYU, Suwon-si (KR); Seungjae LEE, Suwon-si (KR); Kwangseok KIM, Suwon-si (KR)

(73) Assignee: Samsung Electronics Co., Ltd., Suwon-si (KR)

(21) Appl. No.: 18/459,823

(22) Filed: Sep. 1, 2023

(30) Foreign Application Priority Data
Mar. 24, 2023 (KR) 10-2023-0039138
Apr. 18, 2023 (KR) 10-2023-0050896

(51) Int. Cl. G11C 11/16; H01F 10/32; H10B 61/00; H10N 50/10; H10N 50/85

(52) U.S. Cl. CPC G11C 11/161; H01F 10/3272; H01F 10/3286; H10B 61/00; H10N 50/10; H10N 50/85

(57) ABSTRACT

A magnetic tunneling junction device includes a synthetic antiferromagnet, a separation metal layer disposed on the synthetic antiferromagnet, a free layer disposed on the separation metal layer and having a variable magnetization direction, an oxide layer disposed on the free layer, and a pinned layer disposed on the oxide layer and having a pinned magnetization direction. The synthetic antiferromagnet may include a first ferromagnetic layer, a non-magnetic metal layer disposed on the first ferromagnetic layer, and a second ferromagnetic layer disposed on the non-magnetic metal layer. Magnetization directions of the first ferromagnetic layer and the second ferromagnetic layer may be opposite to each other in an in-plane direction and aligned to be inclined with respect to a direction of a current applied to the synthetic antiferromagnet.

### CROSS-REFERENCE TO RELATED APPLICATIONS

This application is based on and claims priority under 35 U.S.C. § 119 to Korean Patent Application Nos. 10-2023-0039138 and 10-2023-0050896, filed on Mar. 24, 2023 and Apr. 18, 2023, respectively, in the Korean Intellectual Property Office, the disclosures of each of which are incorporated by reference herein in their entireties.

### BACKGROUND

### 1. Field

The disclosure relates to magnetic tunneling junction devices capable of magnetic switching without an external magnetic field applied thereto, and memory devices including the magnetic tunneling junction devices.

### 2. Description of the Related Art

A magnetic memory device such as magnetic random access memory (MRAM) stores data by using a change in the resistance of a magnetic tunneling junction device. The resistance of the magnetic tunneling junction device varies with the magnetization direction of a free layer. For example, when the magnetization direction of the free layer is the same as the magnetization direction of a pinned layer, the magnetic tunneling junction device may have a relatively low resistance, and when the magnetization directions are opposite to each other, the magnetic tunneling junction device may have a relatively high resistance. When this characteristic is used in a memory device, for example, the magnetic tunneling junction device having a low resistance may correspond to data ‘0’ and the magnetic tunneling junction device having a high resistance may correspond to data ‘1’.

Such a magnetic memory device has advantages such as non-volatility, high-speed operation, and high durability. For example, spin transfer torque-magnetic RAM (STT-MRAM) that is currently mass-produced may have an operating speed of about 50 nsec to 100 nsec and may also have excellent data retention (e.g., greater than or equal to 10 years). In addition, spin-orbit torque (SOT)-MRAM may have a very fast operation speed less than or equal to 5 nsec, which is faster than that of the STT-MRAM because a spin polarization direction is perpendicular to the magnetization direction. Moreover, the SOT-MRAM may have more stable durability because a path of a write current and a path of a read current are different from each other. However, the SOT-MRAM generally requires an external magnetic field for selective magnetic switching.

### SUMMARY

Provided are magnetic tunneling junction devices capable of selective magnetic switching even without an external magnetic field applied thereto, and memory devices including the magnetic tunneling junction devices.

Additional aspects will be set forth in part in the description which follows and, in part, will be apparent from the description, or may be learned by practice of the presented embodiments of the disclosure.

According to an aspect of an embodiment, a magnetic tunneling junction device includes a synthetic antiferromagnet; a free layer on the synthetic antiferromagnet and having a variable magnetization direction; a separation metal layer between the synthetic antiferromagnet and the free layer; a pinned layer on the separation metal layer and having a pinned magnetization direction; and an oxide layer between the free layer and the pinned layer, wherein the synthetic antiferromagnet comprises a first ferromagnetic layer, a non-magnetic metal layer on the first ferromagnetic layer, and a second ferromagnetic layer on the non-magnetic metal layer, and magnetization directions of the first ferromagnetic layer and the second ferromagnetic layer are opposite each other in an in-plane direction and are configured to be aligned to be inclined with respect to a direction of a current applied to the synthetic antiferromagnet.

The first ferromagnetic layer and the second ferromagnetic layer each may include an alloy of a ferromagnetic metal and a non-magnetic metal.

The ferromagnetic metal may include at least one of iron (Fe), cobalt (Co), or nickel (Ni), and the non-magnetic metal includes at least one of boron (B), silicon (Si), zirconium (Zr), platinum (Pt), palladium (Pd), copper (Cu), or tungsten (W).

At least one of the non-magnetic metal layer or the separation metal layer may include at least one of tantalum (Ta), tungsten (W), palladium (Pd), zirconium (Zr), platinum (Pt), or ruthenium (Ru).

A thickness of each of the non-magnetic metal layer and the separation metal layer may be within a range of about 0.5 nm to about 3 nm.

A magnetization direction of each of the first ferromagnetic layer and the second ferromagnetic layer may be inclined by 10° or more with respect to the direction parallel to the current applied to the synthetic antiferromagnet and inclined by about 20° or more with respect to a direction perpendicular to the current applied to the synthetic antiferromagnet.

An azimuthal angle of the magnetization direction of each of the first ferromagnetic layer and the second ferromagnetic layer with respect to the direction of the current applied to the synthetic antiferromagnet may be within a range of least one of about 10° to about 70°, about 110° to about 170°, about 190° to about 250°, or about 290° to about 350°.

The synthetic antiferromagnet may further include a third ferromagnetic layer between the second ferromagnetic layer and the separation metal layer, and a magnetization direction of the third ferromagnetic layer may be the same as the magnetization direction of the second ferromagnetic layer.

A material of the second ferromagnetic layer and a material of the third ferromagnetic layer may be different from each other.

Each of the free layer and the pinned layer may have perpendicular magnetic anisotropies.

According to an aspect of another embodiment, a memory device includes a plurality of memory cells, each of the plurality of memory cells comprising a magnetic tunneling junction device and a switching device connected to the magnetic tunneling junction device, wherein the magnetic tunneling junction device comprises a synthetic antiferromagnet, a free layer on the synthetic antiferromagnet and having a variable magnetization direction, a separation metal layer between the synthetic antiferromagnet and the free layer, a pinned layer on the free layer and having a pinned magnetization direction, and an oxide layer between the free layer and the pinned layer, and wherein the synthetic antiferromagnet comprises a first ferromagnetic layer, a non-magnetic metal layer on the first ferromagnetic layer, and a second ferromagnetic layer on the non-magnetic metal layer, and magnetization directions of the first ferromagnetic layer and the second ferromagnetic layer are opposite each other in an in-plane direction and are configured to be aligned to be inclined with respect to a direction of a current applied to the synthetic antiferromagnet.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a schematic structure of a magnetic tunneling junction device according to at least one embodiment;

FIGS. 2A and 2B are plan views illustrating a magnetization direction of a synthetic antiferromagnet of the magnetic tunneling junction device shown in FIG. 1;

FIGS. 3A and 3B illustrate an operation of a magnetic tunneling junction device according to at least one embodiment;

FIG. 4 is a graph illustrating variations in magnetization directions of a first ferromagnetic layer and a second ferromagnetic layer according to an intensity of an applied current in a synthetic antiferromagnet of a magnetic tunneling junction device according to at least one embodiment;

FIG. 5 is a diagram illustrating variations in magnetization directions of a first ferromagnetic layer and a second ferromagnetic layer in a synthetic antiferromagnet;

FIG. 6 is a cross-sectional view of a magnetic tunneling junction device including only one ferromagnetic layer instead of a synthetic antiferromagnet according to a comparative example;

FIG. 7 is a graph showing a variation in a magnetization direction of a ferromagnetic layer of a magnetic tunneling junction device according to an intensity of an applied current according to a comparative example;

FIG. 8 is a graph illustrating a relationship between an azimuthal angle of a magnetization direction and a threshold current density in a synthetic antiferromagnet of a magnetic tunneling junction device according to at least one embodiment;

FIG. 9 is a cross-sectional view illustrating a schematic structure of a magnetic tunneling junction device according to at least one embodiment;

FIG. 10 schematically shows a memory cell including a magnetic tunneling junction device according to at least one embodiment;

FIG. 11 is a circuit diagram schematically illustrating a configuration of a memory device including a plurality of memory cells shown in FIG. 10; and

FIG. 12 is a conceptual diagram schematically illustrating a device architecture that may be applied to an electronic device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. When the terms “about” or “substantially” are used in this specification in connection with a numerical value, it is intended that the associated numerical value includes a manufacturing tolerance (e.g., +10%) around the stated numerical value. Further, regardless of whether numerical values are modified as “about” or “substantially,” it will be understood that these values should be construed as including a manufacturing or operational tolerance (e.g., +10%) around the stated numerical values. When referring to “C to D”, this means C inclusive to D inclusive unless otherwise specified.

Hereinafter, with reference to the accompanying drawings, a magnetic tunneling junction device configured for magnetic switching without an external magnetic field, and a memory device including the magnetic tunneling junction device will be described in detail. Like reference numerals refer to like elements throughout, and in the drawings, sizes of elements may be exaggerated for clarity and convenience of explanation. The embodiments described below are merely exemplary, and various modifications may be possible from the embodiments.

In a layer structure described below, an expression “above” or “on” may include not only “immediately on in a contact manner” but also “on in a non-contact manner”. Additionally, spatially relative terms, such as “lower.” “upper,” “above,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly. An expression used in the singular encompasses the expression of the plural, unless it has a clearly different meaning in the context. It will be further understood that the terms “comprises” and/or “comprising” used herein specify the presence of stated features or elements, but do not preclude the presence or addition of one or more other features or elements.

The use of “the” and other demonstratives similar thereto may correspond to both a singular form and a plural form. Unless the order of operations of a method according to the disclosure is explicitly mentioned or described otherwise, the operations may be performed in a proper order. The disclosure is not limited to the order the operations are mentioned.

The term used in the embodiments such as “unit” or “module” indicates a unit for processing at least one function or operation, and may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), and programmable logic unit, a microprocessor, application-specific integrated circuit (ASIC), etc.

The connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language provided herein, is intended merely to better illuminate the disclosure and does not pose a limitation on the scope of the disclosure unless otherwise claimed.

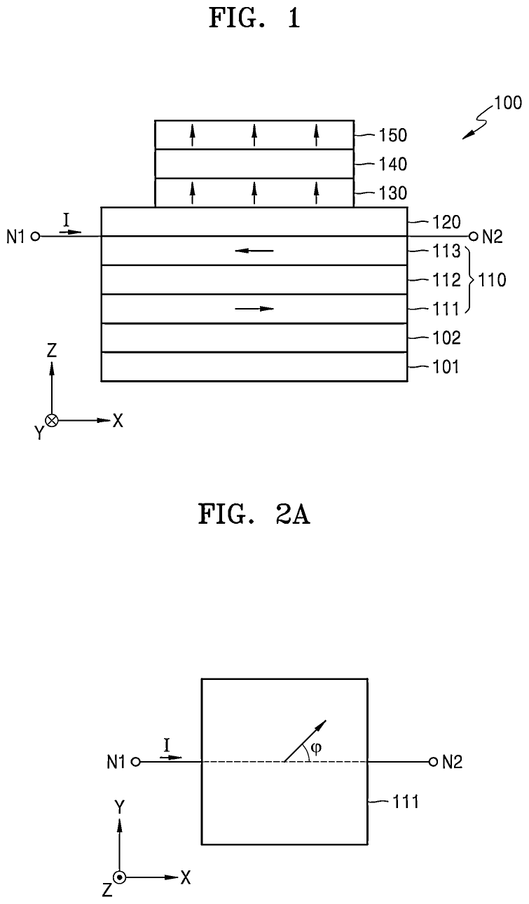

FIG. 1 is a cross-sectional view illustrating a schematic structure of a magnetic tunneling junction device 100 according to at least one embodiment. Referring to FIG. 1, the magnetic tunneling junction device 100 may include a synthetic antiferromagnet 110, a separation metal layer 120 disposed on an upper surface of the synthetic antiferromagnet 110, a free layer 130 disposed on an upper surface of the separation metal layer 120, an oxide layer 140 disposed on an upper surface of the free layer 130, and a pinned layer 150 disposed on an upper surface of the oxide layer 140. In at least one embodiment, the magnetic tunneling junction device 100 may further include a seed layer 101 and a buffer layer 102 disposed on an upper surface of the seed layer 101. In at least one embodiment, the buffer layer 102 serves to assist the magnetization of the synthetic antiferromagnet 110. The synthetic antiferromagnet 110 may be disposed on an upper surface of the buffer layer 102.

Here, the expression “disposed on” is for convenience of description and does not necessarily mean a vertical relationship. In other words, magnetic tunneling junction device 100 may also be described as including the oxide layer 140 disposed between the free layer 130 and the pinned layer 150; the separation metal layer 120 disposed between the free layer 130 and the synthetic antiferromagnet 110; and/or the synthetic antiferromagnet 110 disposed between the buffer layer 102 and the separation metal layer 120.

The free layer 130 and the pinned layer 150 include a ferromagnetic metal material having magnetism. For example, the free layer 130 and the pinned layer 150 may include at least one ferromagnetic material (e.g., selected from the group consisting of iron (Fe), cobalt (Co), nickel (Ni), manganese (Mn), a Fe-containing alloy, a Co-containing alloy, a Ni-containing alloy, a Mn-containing alloy, and a Heusler alloy). The free layer 130 and the pinned layer 150 may have high perpendicular magnetic anisotropy (PMA). For example, the PMA energy of each of the free layer 130 and the pinned layer 150 may exceed a corresponding out-of-plane demagnetization energy. In these cases, the magnetic moment of each of the free layer 130 and the pinned layer 150 may be stabilized in a direction perpendicular to a plane direction (e.g., the X direction) and/or in a thickness direction (e.g., the Z direction). The free layer 130 and the pinned layer 150 may include the same material and/or may include different materials. For example, the free layer 130 may also be doped with at least one non-magnetic metal (e.g., selected from the group consisting of Mg, Ru, Ir, Ti, Zn, Ga, Ta, Al, Mo, Zr, Sn, W, Sb, V, Nb, Cr, Ge, Si, Hf, Tb, Sc, Y, Rh, In, Ca, Sr, Ba, Bc, V, Li, Cd, Pb, Ga, and Mo) such that a magnetization direction of the free layer 130 may be easily changed even with a low current.

The pinned layer 150 has a pinned magnetization direction. In FIG. 1, the pinned layer 150 is magnetized in an out-of-plane direction (e.g., a +Z direction and/or a-Z direction). Once the magnetization direction of the pinned layer 150 is determined, the magnetization direction may not change. On the other hand, the free layer 130 may have a variable magnetization direction. For example, magnetization direction of the free layer 130 may change according to a current applied to the synthetic antiferromagnet 110, such that the free layer 130 may be magnetized in the +Z direction or in the −Z direction according to a direction of the current applied to the synthetic antiferromagnet 110.

The oxide layer 140 serves as a tunnel barrier layer for a magnetic tunneling junction. The oxide layer 140 may include a dielectric oxide such as crystalline Mg oxide. For example, the oxide layer 140 may include at least one of MgO. MgAl₂O₄, and/or MgTiOₓ. In at least one embodiment, the oxide layer 140 may include a single layer and/or a plurality of layers.

The synthetic antiferromagnet 110 may include a first ferromagnetic layer 111, a non-magnetic metal layer 112 disposed on an upper surface of the first ferromagnetic layer 111, and a second ferromagnetic layer 113 disposed on an upper surface of the non-magnetic layer 112. In other words, the first ferromagnetic layer 111 and the second ferromagnetic layer 113 may be disposed such that the upper surface of the first ferromagnetic layer 111 and a lower surface of the second ferromagnetic layer 113 face each other, and the non-magnetic metal layer 112 may be disposed between the first ferromagnetic layer 111 and the second ferromagnetic layer 113. In at least one embodiment, the first ferromagnetic layer 111 may be disposed on the upper surface of the buffer layer 102.

In at least one embodiment, the first ferromagnetic layer 111 and the second ferromagnetic layer 113 include an alloy of a ferromagnetic metal and a non-magnetic material with conductive properties. For example, the ferromagnetic metal may include at least one of iron (Fc), cobalt (Co), nickel (Ni), and/or the like, and the non-magnetic material may include at least one of boron (B), silicon (Si), zirconium (Zr), platinum (Pt), palladium (Pd), copper (Cu), or tungsten (W). In the allow, the non-magnetic material may act as metallically conductive material, and therefore may also be referred to as a “non-magnetic metal” within the context of the first ferromagnetic layer 111 and the second ferromagnetic layer 113. The non-magnetic layer 112 may include a conductive metal that generates Dzyaloshinskii-Moriya interaction on an interface with the first ferromagnetic layer 111 and an interface with the second ferromagnetic layer 113. For example, the non-magnetic metal layer 112 may include at least one of tantalum (Ta), tungsten (W), palladium (Pd), zirconium (Zr), platinum (Pt), ruthenium (Ru), or an alloy including the same.

In such a structure, the first ferromagnetic layer 111 and the second ferromagnetic layer 113 of the synthetic antiferromagnet 110 are configured to form an antiferromagnet by Ruderman-Kittel-Kasuya-Yosida (RKKY) interaction by means of the non-magnetic metal layer 112. In other words, the synthetic antiferromagnet 110 may have a stable state wherein the magnetization direction of the first ferromagnetic layer 111 and the magnetization direction of the second ferromagnetic layer 113 are opposite to each other (e.g., antiparallel) due to, e.g., the coupling of the first ferromagnetic layer 111 and the second ferromagnetic layer 113 through the non-magnetic metal layer 112. In such a structure, the thickness of the non-magnetic metal layer 112 is set to be within an appropriate thickness range for mediating the RKKY interaction. For example, a thickness of the non-magnetic metal layer 112 may be about 0.5 nm or more and about 3 nm or less.

In addition, an arrangement of magnetization states of the first ferromagnetic layer 111 and the second ferromagnetic layer 113 may be determined as a stable state by the Dzyaloshinskii-Moriya interaction occurring on the interface between the non-magnetic metal layer 112 and the first ferromagnetic layer 111 and on the interface between the non-magnetic metal layer 112 and the second ferromagnetic layer 113. The Dzyaloshinskii-Moriya interaction represents a property in which a magnetization direction of a ferromagnetic material rotates clockwise or counterclockwise according to the intensity of a spin-orbit interaction occurring on an interface between the non-magnetic metal and the ferromagnetic material. Therefore, when the non-magnetic metal layer 112 (including a metal material that is prone to the Dzyaloshinskii-Moriya interaction on the interface with the ferromagnetic material) is disposed between the first ferromagnetic layer 111 and the second ferromagnetic layer 113, it is possible to design the synthetic antiferromagnet 110 having a stable magnetic state based on the RKKY interaction and the Dzyaloshinskii-Moriya interaction.

According to at least one embodiment, as indicated by arrows in FIG. 1, each of the first ferromagnetic layer 111 and the second ferromagnetic layer 113 may have magnetic anisotropy in a horizontal direction or an in-plane direction (i.e., in a direction parallel to an X-Y plane). In other words, each of the first ferromagnetic layer 111 and the second ferromagnetic layer 113 may have horizontal magnetic anisotropy. Accordingly, the magnetization directions of the first ferromagnetic layer 111 and the second ferromagnetic layer 113 may be parallel to the upper or lower surfaces of the first ferromagnetic layer 111 and the second ferromagnetic layer 113.

Also, according to at least one embodiment, the magnetization directions of the first ferromagnetic layer 111 and the second ferromagnetic layer 113 may be aligned to be inclined in the direction of the current applied to the synthetic antiferromagnet 110. For example, when a first node N1 and a second node N2 for applying the current are disposed on both sides of the synthetic antiferromagnet 110 in the X direction, the current may flow through the synthetic antiferromagnet 110 in the X direction. In this case, the magnetization directions of the first ferromagnetic layer 111 and the second ferromagnetic layer 113 may have directions inclined with respect to the X direction in the X-Y plane and may be opposite to each other (e.g., antiparallel).

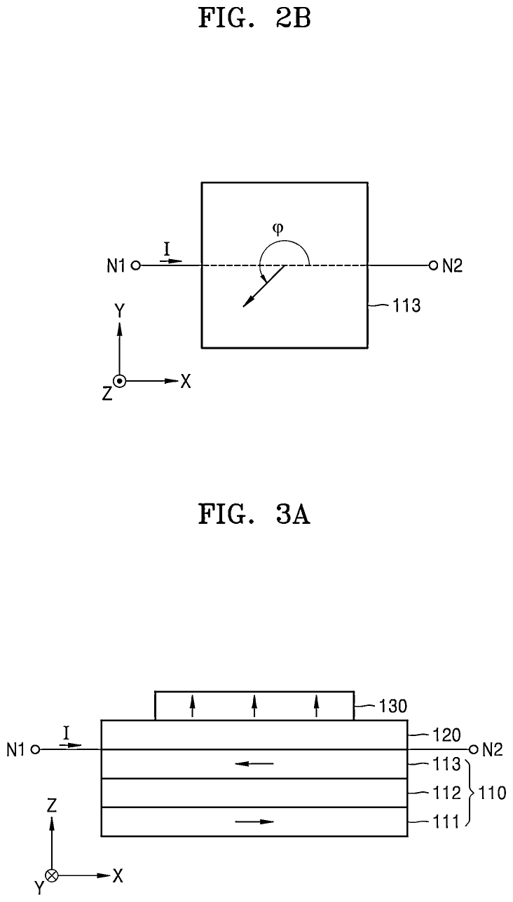

FIGS. 2A and 2B are plan views illustrating a magnetization direction of the synthetic antiferromagnet 110 of the magnetic tunneling junction device 100 shown in FIG. 1 Referring to FIGS. 2A and 2B, magnetization directions of the first ferromagnetic layer 111 and the second ferromagnetic layer 113 may be aligned to be inclined by an azimuthal angle “φ” with respect to a direction of a current in an X-Y plane. Therefore, when the current applied to the synthetic antiferromagnet 110 flows in the X direction, the magnetization directions of the first ferromagnetic layer 111 and the second ferromagnetic layer 113 may not be parallel to the X direction. For example, the azimuthal angle φ of the magnetization direction of each of the first and second ferromagnetic layers 111 and 113 with respect to the direction of the current applied to the synthetic antiferromagnet 110 may be about 10° or more, about 70° or less, about 110° or more and about 170° or less, about 190° or more and about 250° or less, and/or about 290° or more and about 350° or less. Here, the azimuthal angle q may be defined as a counterclockwise angle of the magnetization directions of the first and second ferromagnetic layers 111 and 113 with respect to the direction of the current in the X-Y plane.

The azimuthal angle φ of the magnetization directions of the first ferromagnetic layer 111 and the second ferromagnetic layer 113 may be adjusted by applying an external magnetic field together with a heat treatment (e.g., during or after depositing the first ferromagnetic layer 111 and/or the second ferromagnetic layer 113). For example, by applying the external magnetic field to the first ferromagnetic layer 111 and the second ferromagnetic layer 113 in a direction inclined to the direction of the current to be applied to the synthetic antiferromagnet 110, the magnetization directions of the first ferromagnetic layer 111 and the second ferromagnetic layer 113 may be inclined in the direction of the current to be applied to the synthetic antiferromagnet 110.

Meanwhile, in FIGS. 2A and 2B, the magnetization directions of the first ferromagnetic layer 111 and the second ferromagnetic layer 113 are perfectly antiparallel to each other. In other words, the magnetization direction of the first ferromagnetic layer 111 is 180° in the magnetization direction of the second ferromagnetic layer 113. In this case, a difference between the azimuthal angle q of the magnetization direction of the first ferromagnetic layer 111 and the azimuthal angle of the magnetization direction φ of the second ferromagnetic layer 113 may be regarded as 180°. However, according to materials and thicknesses of the first ferromagnetic layer 111 and the second ferromagnetic layer 113, the difference between the azimuthal angle φ of the magnetization direction of the first ferromagnetic layer 111 and the azimuthal angle of the magnetization direction q of the second ferromagnetic layer 113 may be slightly greater or slightly smaller than 180°. For example, when the first ferromagnetic layer 111 and the second ferromagnetic layer 113 have different materials and/or different thicknesses, the magnetization direction of the first ferromagnetic layer 111 and the magnetization direction of the second ferromagnetic layer 113, which have stable magnetization states by an RKKY interaction and a Dzyaloshinskii-Moriya interaction, may slightly deviate from “true” antiparallel. In other words, the actual magnetization directions of the first ferromagnetic layer 111 and the second ferromagnetic layer 113 may be determined by various factors such as materials and thicknesses of the first ferromagnetic layer 111 and the second ferromagnetic layer 113, a manufacturing process, a direction of an external magnetic field applied during the manufacturing process, etc.

The separation metal layer 120 may serve as a spacer that separates the free layer 130 and the second ferromagnetic layer 113 from each other so that a magnetization direction of the free layer 130 is not affected by the magnetization direction of the second ferromagnetic layer 113. In addition, the separation metal layer 120 may serve to transfer current to the free layer 130. In addition, the separation metal layer 120 may be configured to cause the Zalosinski-Moriya interaction on the interface with the second ferromagnetic layer 113. To this end, the separation metal layer 120 may have the same conductive non-magnetic metal material and the same thickness as the non-magnetic metal layer 112. For example, the separation metal layer 120 may include at least one of tantalum (Ta), tungsten (W), palladium (Pd), zirconium (Zr), platinum (Pt), ruthenium (Ru), and/or an alloy including the same. Also, a thickness of the separation metal layer 120 may be, for example, about 0.5 nm or more and about 3 nm or less.

The synthetic antiferromagnet 110 having an in-plane (e.g., in an X-Y plane) magnetization direction may serve to selectively switch the magnetization direction of the free layer 130 without an external magnetic field. When a current is applied to the synthetic antiferromagnet 110 and/or the separation metal layer 120, a spin current may be generated, and a polarization direction of the spin current may have a direction perpendicular to the in-plane (i.e., in the X-Y plane). This spin current may generate a spin-orbit torque in the free layer 130. Accordingly, the magnetization direction of the free layer 130 may be selectively switched when a current greater than or equal to a threshold current is applied to the synthetic antiferromagnet 110 and/or the separation metal layer 120. Accordingly, the magnetic tunneling junction device 100 according to at least one embodiment may operate without application of an external magnetic field.

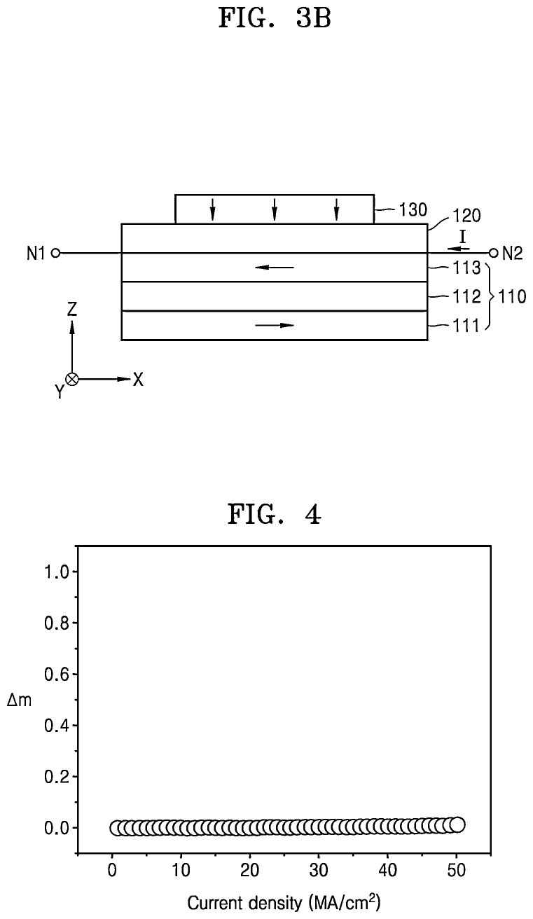

FIGS. 3A and 3B illustrate an operation of the magnetic tunneling junction device 100 according to at least one embodiment. For simplicity of illustration, elements which are configured to be not affected by the operation are omitted in the drawings. Referring to FIG. 3A, when a current is applied to the synthetic antiferromagnet 110 and/or the separation metal layer 120 in a direction from the first node N1 to the second node N2, the current may flow in the +X direction. When an intensity of the current is greater than or equal to a threshold current, a magnetization direction of the free layer 130 may be switched to the +Z direction. In addition, referring to FIG. 3B, when a current is applied to the synthetic antiferromagnet 110 and/or the separation metal layer 120 in a direction from the second node N2 to the first node N1, the current may flow in the −X direction. When the intensity of the current is greater than or equal to the threshold current, the magnetization direction of the free layer 130 may be switched to the −Z direction. In FIGS. 3A and 3B, magnetization directions of the first ferromagnetic layer 111, the second ferromagnetic layer 113, and the free layer 130 and an application direction of the current are only examples for convenience of description, and are not necessarily limited thereto. In the actually manufactured magnetic tunneling junction device 100, the magnetization directions of the first ferromagnetic layer 111, the second ferromagnetic layer 113, and the free layer 130 and the application direction of the current may be different from those illustrated in FIGS. 3A and 3B.

As described above, the synthetic antiferromagnet 110 has a stable magnetization state when the magnetization direction of the first ferromagnetic layer 111 and the magnetization direction of the second ferromagnetic layer 113 are opposite to each other. Because the synthetic antiferromagnet 110 has a stable magnetization state, even though a current is repeatedly applied to the synthetic antiferromagnet 110, only the magnetization direction of the free layer 130 may change, and the magnetization directions of the first ferromagnetic layer 111 and the second ferromagnetic layer 113 may not change. Therefore, the magnetic tunneling junction device 100 according to at least one embodiment may have high operational stability.

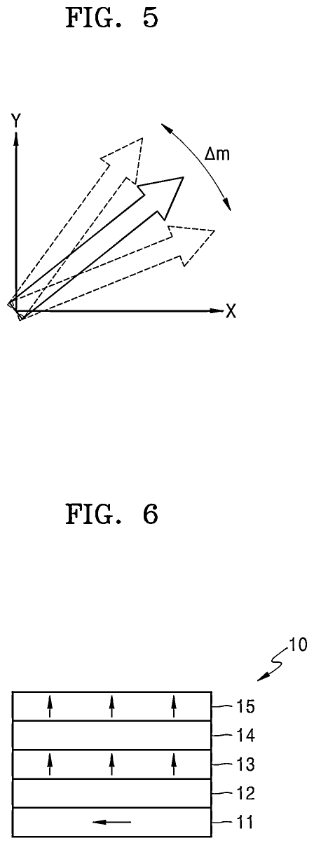

FIG. 4 is a graph illustrating variations in magnetization directions of the first ferromagnetic layer 111 and the second ferromagnetic layer 113 according to an intensity of an applied current in the synthetic antiferromagnet 110 of the magnetic tunneling junction device 100 according to at least one embodiment. In the graph of FIG. 4, the horizontal axis represents a current density of a current applied to the synthetic antiferromagnet 110, and the vertical axis represents a normalized variation of the magnetization direction. FIG. 5 is a diagram illustrating variations in magnetization directions of the first ferromagnetic layer 111 and the second ferromagnetic layer 113 in the synthetic antiferromagnet 110. Referring to FIG. 5, the variation of the magnetization direction is a degree to which the magnetization directions of the first ferromagnetic layer 111 and the second ferromagnetic layer 113 change in an azimuthal direction in an in-plane.

Referring to FIG. 4, even though the current density of the current applied to the synthetic antiferromagnet 110 increases, the magnetization directions of the first ferromagnetic layer 111 and the second ferromagnetic layer 113 hardly change. Through this, it may be seen that the synthetic antiferromagnet 110 exhibits low reactivity with respect to a spin current and a spin-orbit torque generated by the current applied to the synthetic antiferromagnet 110, and regardless of the intensity of the applied current, a change in the magnetization direction within the synthetic antiferromagnet 110 is very small. Therefore, the synthetic antiferromagnet 110 may have high stability with its magnetization direction always pinned and perform magnetic switching on the free layer 130, and the magnetic tunneling junction device 100 may have excellent operational stability.

In order to compare a magnetic tunneling junction device not including the synthetic antiferromagnet 110 with the magnetic tunneling junction device 100 according to the above example, simulation was performed on a comparative magnetic tunneling junction device not including the synthetic antiferromagnet 110. FIG. 6 is a cross-sectional view of the comparative magnetic tunneling junction device 10 including only one ferromagnetic layer instead of the synthetic antiferromagnet. Referring to FIG. 6, the magnetic tunneling junction device 10 according to the comparative example includes a ferromagnetic layer 11, a separation metal layer 12, a free layer 13, an oxide layer 14, and a pinned layer 15. The ferromagnetic layer 11 has magnetic anisotropy in a horizontal direction (e.g., in an in-plane direction).

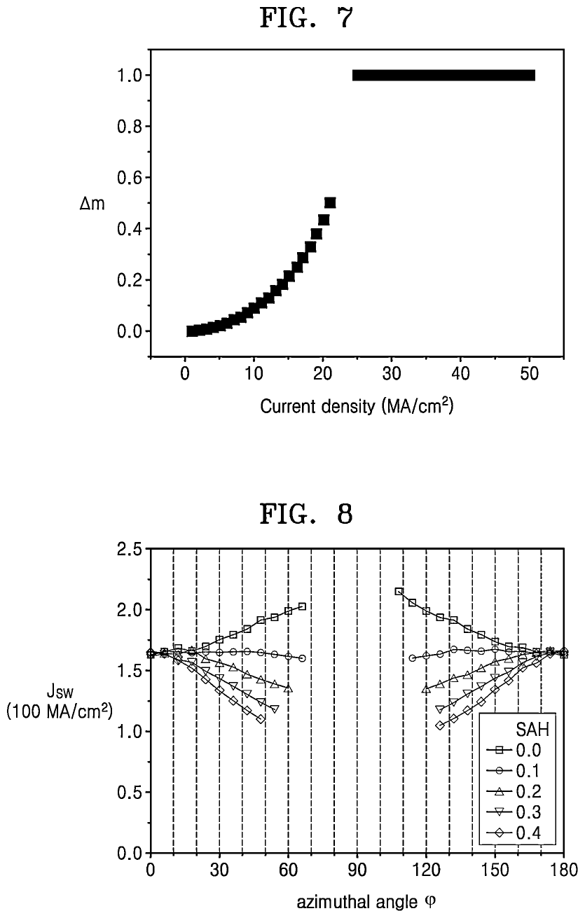

FIG. 7 is a graph showing a variation in a magnetization direction of the ferromagnetic layer 11 of the comparative magnetic tunneling junction device 10 according to an intensity of an applied current. Referring to FIG. 7, it may be seen that the magnetization direction of the ferromagnetic layer 11 greatly changes by a current applied to the ferromagnetic layer 11. Therefore, the magnetic tunneling junction device 10 according to the comparative example having only one ferromagnetic layer 11 may not perform based on a stable operation.

Meanwhile, a spin current generated in the synthetic antiferromagnet 110 may include a spin hall current, a spin anomalous hall current, and/or an interfacial spin current. The spin hall current is a spin current due to the spin hall effect generated based on a spin-orbit interaction in a ferromagnetic metal and a non-magnetic metal. The spin anomalous hall current is a spin current due to the spin anomalous hall effect generated based on the spin-orbit interaction of a ferromagnetic metal. In addition, the interfacial spin current is a spin current generated on the interface between the synthetic antiferromagnet 110 and the separation metal layer 120. In addition, the interfacial spin current may be also generated on the interface between the non-magnetic metal layer 112 and the first ferromagnetic layer 111 and the interface between the non-magnetic metal layer 112 and the second ferromagnetic layer 113 in the synthetic antiferromagnet 110.

In particular, the spin anomalous hall current may be generated when magnetization directions of the first ferromagnetic layer 111 and the second ferromagnetic layer 113 are not parallel to the direction of the applied current. Therefore, because the first ferromagnetic layer 111 and the second ferromagnetic layer 113 have magnetization directions inclined with respect to the direction of the applied current, the spin anomalous hall current may be further generated, and thus, the spin current may increase. Therefore, the intensity of a threshold current for magnetic switching of the free layer 130 may be lowered, and thus, the operation efficiency of the magnetic tunneling junction device 100 may be improved.

FIG. 8 is a graph illustrating a relationship between an azimuthal angle of a magnetization direction and a threshold current density in the synthetic antiferromagnet 110 of the magnetic tunneling junction device 100 according to at least one embodiment. In the graph of FIG. 8, the horizontal axis represents the azimuthal angle of the magnetization direction of the first ferromagnetic layer 111, and the vertical axis represents an intensity of the threshold current density. In addition, a value of the Spin Anomalous Hall effect (SAH) is a dimensionless constant value as a coefficient of the term representing a spin anomalous Hall current in an equation for calculating a spin current. The value of SAH being 0.0 may mean that there is no spin anomalous Hall current component in the spin current.

Referring to FIG. 8, there is no significant change in the threshold current density while the azimuthal angle of the magnetization direction increases from 0° to about 10°. In addition, when the azimuthal angle of the magnetization direction is 10° or more, it may be seen that the threshold current density decreases significantly as the azimuthal angle of the magnetization direction increases. In particular, the greater the value of SAH, the lower the threshold current density may be. On the other hand, when the value of SAH is 0.0, the threshold current density rather increases as the azimuthal angle of the magnetization direction increases, and when the value of SAH is 0.1, there is no significant change in the threshold current density even when the azimuthal angle of the magnetization direction increases.

Further, when the azimuthal angle of the magnetization direction is greater than about 70°, as other factors (e.g., a spin Hall current component and an interfacial spin current component) other than the spin anomalous Hall current component decrease, magnetic switching does not occur in the free layer 130. Therefore, the magnetization directions of the first ferromagnetic layer 111 and the second ferromagnetic layer 113 in the synthetic antiferromagnet 110 may be selected to be inclined with respect to a direction parallel to the applied current by about 10° or more, and to be inclined with respect to a direction perpendicular to the current by about 20° or more. For example, the azimuthal angle of the magnetization directions of the first ferromagnetic layer 111 and the second ferromagnetic layer 113 in the synthetic antiferromagnet 110 may be about 10° or more and about 70° or less, about 110° or more, about 170° or less, about 190° or more and about 250° or less, or about 290° or more and about 350° or less.

Further, the value of SAH may vary depending on the materials of the first ferromagnetic layer 111 and the second ferromagnetic layer 113. When a material in which spin-orbit interaction does not occur or weakly occurs is used, even though the magnetization directions of the first ferromagnetic layer 111 and the second ferromagnetic layer 113 are aligned to be inclined with respect to the applied current, the spin anomalous hall current hardly occurs, which makes it difficult to obtain the effect of lowering the threshold current. Accordingly, an alloy of at least one ferromagnetic metal of iron (Fe), cobalt (Co), or nickel (Ni), and at least one non-magnetic metal of boron (B), silicon (Si), zirconium (Zr), platinum (Pt), palladium (Pd), copper (Cu), and tungsten (W) is used as the material of the first and second ferromagnetic layers 111 and 113, and the magnetization directions of the first ferromagnetic layer 111 and the second ferromagnetic layer 113 are aligned to be inclined with respect to the applied current, and thus, the threshold current for magnetic switching of the free layer may be lowered.

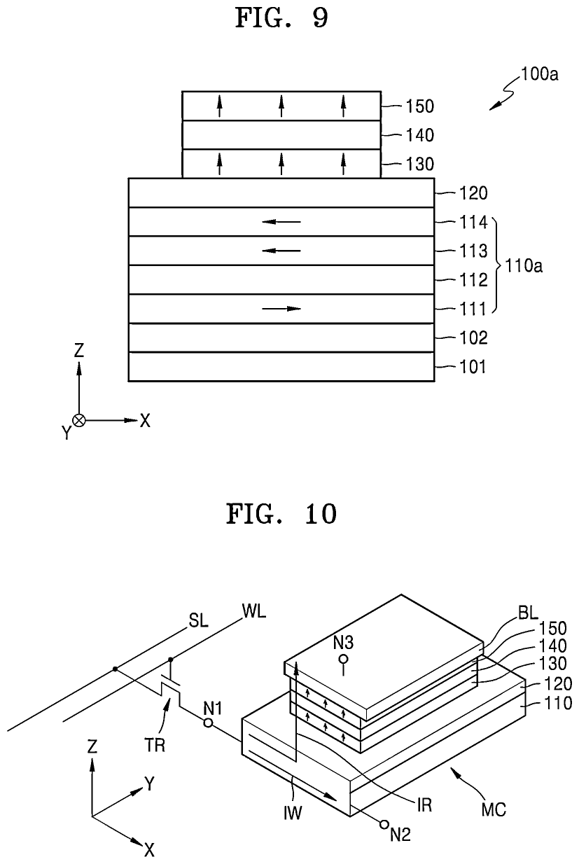

FIG. 9 is a cross-sectional view illustrating a schematic structure of a magnetic tunneling junction device 100a according to at least one embodiment. Referring to FIG. 9, the magnetic tunneling junction device 100a includes the synthetic antiferromagnet 110a, the separation metal layer 120 disposed on an upper surface of the synthetic antiferromagnet 110a, the free layer 130 disposed on an upper surface of the separation metal layer 120, an oxide layer 140 disposed on an upper surface of the free layer 130, and the pinned layer 150 disposed on an upper surface of the oxide layer 140. In at least one embodiment, the magnetic tunneling junction device 100a may further include a seed layer 101, and a buffer layer 102 disposed between an upper surface of the seed layer 101 and a bottom surface of the synthetic antiferromagnet 110a.

The synthetic antiferromagnet 110a may include the first ferromagnetic layer 111, the non-magnetic metal layer 112 disposed on an upper surface of the first ferromagnetic layer 111, the second ferromagnetic layer 113 disposed on an upper surface of the non-magnetic metal layer 112, and a third ferromagnetic layer 114 disposed on an upper surface of the second ferromagnetic layer 113. In this case, the separation metal layer 120 may be disposed on an upper surface of the third ferromagnetic layer 114. In other words, the third ferromagnetic layer 114 may be disposed between the second ferromagnetic layer 113 and the separation metal layer 120. Therefore, the magnetic tunneling junction device 100a shown in FIG. 9 is different from the magnetic tunneling junction device 100 shown in FIG. 1 in that the magnetic tunneling junction device 100a further includes the third ferromagnetic layer 114. The remaining configurations of the magnetic tunneling junction device 100a are the same as (or substantially similar to) those of the magnetic tunneling junction device 100 shown in FIG. 1, and thus, detailed descriptions thereof are omitted.

The third ferromagnetic layer 114 may include, for example, an alloy of at least one ferromagnetic metal of iron (Fe), cobalt (Co), and/or nickel (Ni) and at least one non-magnetic metal of boron (B), silicon (Si), zirconium (Zr), platinum (Pt), palladium (Pd), copper (Cu), and/or tungsten (W). The second ferromagnetic layer 113 and the third ferromagnetic layer 114 may include different materials and may have the same magnetization direction in an in-plane. By further including the third ferromagnetic layer 114, the stability of the synthetic antiferromagnet 110a may be further improved, and a spin current generated in the synthetic antiferromagnet 110a may be further increased when a current is applied.

The above-described magnetic tunneling junction devices 100 and 100a may have a relatively low resistance when a magnetization direction of the free layer 130 and a magnetization direction of the pinned layer 150 are the same, and may have a relatively a high resistance when the magnetization directions are different from each other. This phenomenon is called tunneling magnetoresistance (TMR). The magnetic tunneling junction devices 100 and 100a may be used in a memory device by applying this TMR phenomenon. In particular, because selective magnetic switching of the free layer 130 is possible without application of an external magnetic field, the memory device including the magnetic tunneling junction devices 100 and 100a according to at least one embodiment may be capable of high-speed operation without having a complicated structure for application of the external magnetic field.

FIG. 10 schematically shows a memory cell MC including the magnetic tunneling junction device 100 according to at least one embodiment. Referring to FIG. 10, the memory cell MC may include the magnetic tunneling junction device 100 and a switching device TR connected to the magnetic tunneling junction device 100. The switching device TR may be a thin film transistor. The memory cell MC may be connected between a bit line BL and a word line WL. The bit line BL and the word line WL may be disposed to cross each other, and the memory cell MC may be disposed in an intersection point of the bit line BL and the word line WL. The bit line BL may be electrically connected to the pinned layer 150 of the magnetic tunneling junction device 100 and the word line WL may be connected to a gate of the switching device TR. In addition, a first source/drain electrode of the switching device TR may be electrically connected to the synthetic antiferromagnet 110 of the magnetic tunneling junction device 100 and/or the separation metal layer 120 and a second source/drain electrode of the switching device TR may be electrically connected to a source line SL. In FIG. 10, the memory cell MC may include the magnetic tunneling junction device 100 shown in FIG. 1, but in some embodiments, the memory cell MC may include the magnetic tunneling junction device 100a shown in FIG. 9.

In this structure, a write current IW and a read current IR may be applied to the memory cell MC through the word line WL and the bit line BL. For example, the write current IW greater than or equal to a threshold current may flow through a path between the first node N1 and the second node N2 on both sides of the synthetic antiferromagnet 110. To this end, the first source/drain electrode of the switching device TR may be connected to the first node N1 of the synthetic antiferromagnet 110. The second node N2 of the synthetic antiferromagnet 110 may be grounded. Then, a magnetization direction of the free layer 130 may change in the +Z direction or the −Z direction according to a direction of the current applied to the synthetic antiferromagnet 110. Also, the read current IR may flow through a path between the first node N1 of the synthetic antiferromagnet 110 and a third node N3 of the bit line BL. For example, a resistance value of the magnetic tunneling junction device 100 may be read by applying a current lower than the threshold current to the first node N1 and measuring the current flowing between the synthetic antiferromagnet 110 and the bit line BL.

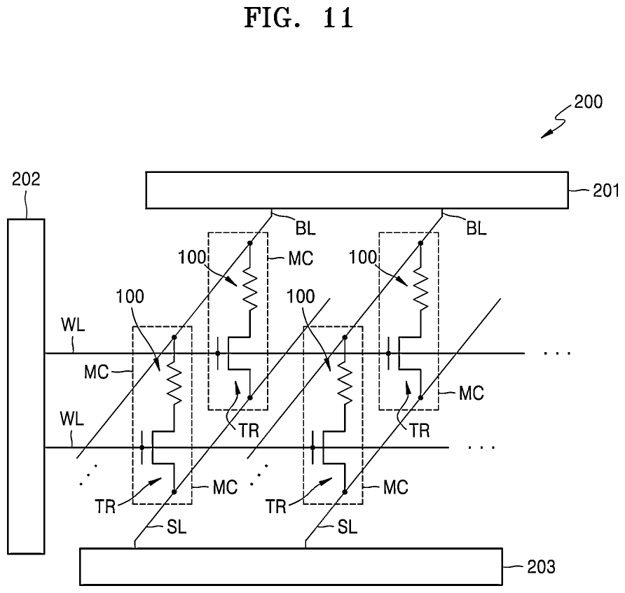

FIG. 11 is a circuit diagram schematically illustrating a configuration of a memory device 200 including a plurality of the memory cell MC shown in FIG. 10. Referring to FIG. 11, the memory device 200 may include a plurality of bit lines BL, a plurality of word lines WL, a plurality of source lines SL, the plurality of memory cells MCs respectively disposed in intersection points of the plurality of bit lines BL and the plurality of word lines WL, a bit line driver 201 receiving current from the plurality of bit lines BL, a word line driver 202 applying current to the plurality of word lines WL and a source line driver 203 applying current to the plurality of source lines SL. Each memory cell MC may have the configuration shown in FIG. 10. The memory device 200 illustrated in FIG. 11 may be a magnetic random access memory (MRAM), and may be used in electronic devices using nonvolatile memory. In particular, the memory device 200 illustrated in FIG. 11 may be a SOT-MRAM according to at least one embodiment.

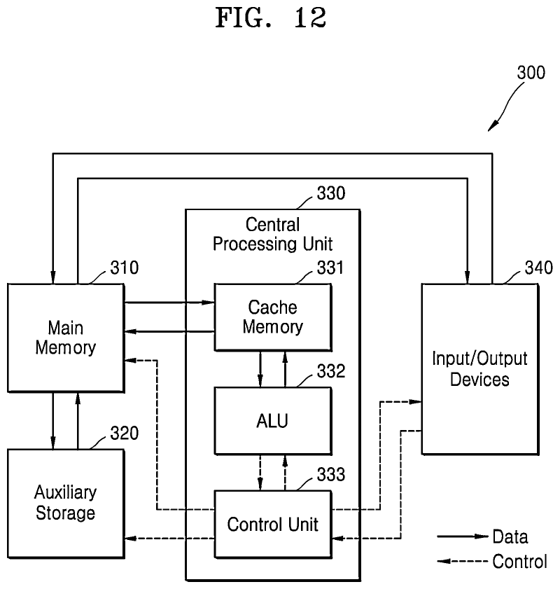

The above-described memory device 200 may be used for data storage in various electronic devices. FIG. 12 is a conceptual diagram schematically illustrating a device architecture that may be applied to an electronic device 300. Referring to FIG. 12, the electronic device 300 may include a main memory 310, an auxiliary storage 320, a central processing unit (CPU) 330, and an input/output device 340. The CPU 330 may include a cache memory 331, an arithmetic logic unit (ALU) 332, and a control unit 333. The cache memory 331 may include static random access memory (SRAM). The main memory 310 may include a DRAM device, and the auxiliary storage 320 may include the memory device 200 according to at least one embodiment. Alternatively, at least one or all of the cache memory 331, the main memory 310, and/or the auxiliary storage 320 may include the memory device 200 according to at least one embodiment. In some cases, the electronic device 300 may be implemented in a form in which computing unit devices and memory unit devices are adjacent to each other in one chip without distinction between the above-described sub-units.

Selective magnetic switching of the magnetic tunneling junction device according to at least one embodiment may be possible without application of an external magnetic field. Therefore, a high-speed operation of the memory device including the magnetic tunneling junction device according to at least one embodiment may be possible without a complicated structure for applying an external magnetic field.

In addition, the magnetic tunneling junction device according to at least one embodiment may include a synthetic antiferromagnet having a magnetization direction inclined in a direction of an applied current. Therefore, the intensity of a threshold current for magnetic switching may be lowered, and thus, the operating efficiency of the magnetic tunneling junction device may be improved. In addition, a magnetization direction of the synthetic antiferromagnet does not change with the applied current, and thus, a stable operation of the magnetic tunneling junction device according to at least one embodiment may be possible.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A magnetic tunneling junction device comprising:
a synthetic antiferromagnet;
a free layer on the synthetic antiferromagnet and having a variable magnetization direction;
a separation metal layer between the synthetic antiferromagnet and the free layer;
a pinned layer on the separation metal layer and having a pinned magnetization direction; and
an oxide layer between the free layer and the pinned layer,
wherein the synthetic antiferromagnet comprises
a first ferromagnetic layer,
a non-magnetic metal layer on the first ferromagnetic layer, and
a second ferromagnetic layer on the non-magnetic metal layer, and
magnetization directions of the first ferromagnetic layer and the second ferromagnetic layer are opposite each other in an in-plane direction and are configured to be aligned to be inclined with respect to a direction of a current applied to the synthetic antiferromagnet.

2. The magnetic tunneling junction device of claim 1, wherein the first ferromagnetic layer and the second ferromagnetic layer each include an alloy of a ferromagnetic metal and a non-magnetic metal.

3. The magnetic tunneling junction device of claim 2, wherein
the ferromagnetic metal includes at least one of iron (Fe), cobalt (Co), or nickel (Ni), and
the non-magnetic metal includes at least one of boron (B), silicon (Si), zirconium (Zr), platinum (Pt), palladium (Pd), copper (Cu), or tungsten (W).

4. The magnetic tunneling junction device of claim 1, wherein at least one of the non-magnetic metal layer or the separation metal layer include at least one of tantalum (Ta), tungsten (W), palladium (Pd), zirconium (Zr), platinum (Pt), or ruthenium (Ru).

5. The magnetic tunneling junction device of claim 1, wherein a thickness of each of the non-magnetic metal layer and the separation metal layer is within a range of about 0.5 nm to about 3 nm.

6. The magnetic tunneling junction device of claim 1, wherein the magnetization directions of the first ferromagnetic layer and the second ferromagnetic layer are inclined by 10° or more with respect to the direction parallel to the current applied to the synthetic antiferromagnet and is inclined by about 20° or more with respect to a direction perpendicular to the current applied to the synthetic antiferromagnet.

7. The magnetic tunneling junction device of claim 1, wherein an azimuthal angle of the magnetization directions of each of the first ferromagnetic layer and the second ferromagnetic layer with respect to the direction of the current applied to the synthetic antiferromagnet is within a range of least one of about 10° to about 70°, about 110° to about 170°, about 190° to about 250°, or about 290° to about 350°.

8. The magnetic tunneling junction device of claim 1, wherein
the synthetic antiferromagnet further includes a third ferromagnetic layer between the second ferromagnetic layer and the separation metal layer, and
a magnetization direction of the third ferromagnetic layer is a same direction as the magnetization direction of the second ferromagnetic layer.

9. The magnetic tunneling junction device of claim 8, wherein a material of the second ferromagnetic layer and a material of the third ferromagnetic layer are different from each other.

10. The magnetic tunneling junction device of claim 1, wherein the free layer and the pinned layer have perpendicular magnetic anisotropies.

11. A memory device comprising:
a plurality of memory cells, each of the plurality of memory cells comprising a magnetic tunneling junction device and a switching device connected to the magnetic tunneling junction device,
wherein the magnetic tunneling junction device comprises
a synthetic antiferromagnet,
a free layer on the synthetic antiferromagnet and having a variable magnetization direction,
a separation metal layer between the synthetic antiferromagnet and the free layer,
a pinned layer on the free layer and having a pinned magnetization direction, and
an oxide layer between the free layer and the pinned layer, and
wherein the synthetic antiferromagnet comprises
a first ferromagnetic layer,
a non-magnetic metal layer on the first ferromagnetic layer, and
a second ferromagnetic layer on the non-magnetic metal layer, and
magnetization directions of the first ferromagnetic layer and the second ferromagnetic layer are opposite each other in an in-plane direction and are configured to be aligned to be inclined with respect to a direction of a current applied to the synthetic antiferromagnet.

12. The memory device of claim 11, wherein the first ferromagnetic layer and the second ferromagnetic layer each include an alloy of a ferromagnetic metal and a non-magnetic metal.

13. The memory device of claim 12, wherein
the ferromagnetic metal includes at least one of iron (Fe), cobalt (Co), or nickel (Ni), and
the non-magnetic metal includes at least one of boron (B), silicon (Si), zirconium (Zr), platinum (Pt), palladium (Pd), copper (Cu), or tungsten (W).

14. The memory device of claim 11, wherein at least one of the non-magnetic metal layer or the separation metal layer include at least one of tantalum (Ta), tungsten (W), palladium (Pd), zirconium (Zr), platinum (Pt), or ruthenium (Ru).

15. The memory device of claim 11, wherein a thickness of each of the non-magnetic metal layer and the separation metal layer is within a range of about 0.5 nm to about 3.

16. The memory device of claim 11, wherein the magnetization directions of the first ferromagnetic layer and the second ferromagnetic layer are inclined by 10° or more with respect to the direction parallel to the current applied to the synthetic antiferromagnet and is inclined by about 20° or more with respect to a direction perpendicular to the current applied to the synthetic antiferromagnet.

17. The memory device of claim 11, wherein an azimuthal angle of the magnetization directions of each of the first ferromagnetic layer and the second ferromagnetic layer with respect to the direction of the current applied to the synthetic antiferromagnet is within a range of least one of about 10° to about 70°, about 110° to about 170°, about 190° to about 250°, or about 290° to about 350°.

18. The memory device of claim 11, wherein
the synthetic antiferromagnet further includes a third ferromagnetic layer between the second ferromagnetic layer and the separation metal layer, and
a magnetization direction of the third ferromagnetic layer is a same direction as the magnetization direction of the second ferromagnetic layer.

19. The memory device of claim 18, wherein a material of the second ferromagnetic layer and a material of the third ferromagnetic layer are different from each other.

20. The memory device of claim 11, wherein the free layer and the pinned layer have perpendicular magnetic anisotropies.
